(19) United States
(12) Patent Application Publication
(10) Pub. No.: US 2021/0359248 A1
(43) Pub. Date: Nov. 18, 2021

(54) DISPLAY PANEL AND MANUFACTURING METHOD THEREOF

(71) Applicant: Shenzhen China Star Optoelectronics Semiconductor Display Technology Co., LTD., Shenzhen, Guangdong (CN)

(72) Inventors: Chunhsiung FANG, Shenzhen, Guangdong (CN); Yuanchun WU, Shenzhen, Guangdong (CN); Poyen LU, Shenzhen, Guangdong (CN)

(21) Appl. No.: 16/613,085

(22) PCT Filed: Jul. 29, 2019
(86) PCT No.: PCT/CN2019/098095

§ 371 Date: Nov. 12, 2019

(30) Foreign Application Priority Data
Apr. 18, 2019 (CN) 201910314205.X

(51) Int. Cl. H01L 51/52; H01L 27/32; H01L 51/56

(52) U.S. Cl. CPC H01L 51/5228; H01L 27/322; H01L 2227/323; H01L 51/5284; H01L 27/3244; H01L 51/56

(57) ABSTRACT

The present disclosure provides a display panel and a manufacturing method thereof, the display panel comprises an array substrate and a color filter substrate; the array substrate comprises an anode, a light-emitting layer and a cathode, the light-emitting layer is disposed correspondingly to a pixel area on the array substrate; the color filter substrate comprises color filters corresponding to the pixel area, and black matrices disposed between the adjacent color filters; the color filter substrate provided with auxiliary cathodes corresponding to the black matrices, and metal layers disposed on the auxiliary cathodes; the cathode is in parallel contact with the auxiliary cathodes through the metal layers.

### FIELD OF INVENTION

The present disclosure relates to the field of display technologies, and more particularly to a display panel and a manufacturing method thereof.

### BACKGROUND OF INVENTION

In AMOLED displays, top emitting AMOLED display devices are more convenient for display resolutions to be improved. To make light transmit through a cathode, the cathode is usually a transparent or translucent material. However, a high square resistance of the cathode causes a voltage drop and leads to non-uniform brightness of display devices. A current practice is disposing an auxiliary cathode on a color filter substrate to improve this situation, but when a substrate surface of the auxiliary cathode is uneven, or not controlling a spacing between two glass substrates when bonding, it's easy to cause poor contact between an auxiliary cathode and an OLED cathode, thereby losing expected function of the auxiliary cathode and non-uniform brightness of display devices is still present.

Therefore, it needs a solution to solve the problem in prior art.

### SUMMARY OF INVENTION

The present disclosure provides a display panel and a manufacturing method thereof to improve poor contact between an auxiliary cathode and a cathode, thereby improving non-uniform brightness of display panels.

To achieve the above object, an embodiment of the present disclosure provides a display panel. The display panel comprises an array substrate and a color filter substrate disposed opposite to the array substrate. The array substrate comprises an anode, a cathode and a light-emitting layer disposed between the anode and the cathode; the array substrate is provided with a pixel area, and the light-emitting layer is disposed correspondingly to the pixel area. The color filter substrate comprises color filters corresponding to the pixel area, and black matrices disposed between two of the adjacent color filters; the color filter substrate is provided with auxiliary cathodes corresponding to the black matrices, and metal layers are disposed on the auxiliary cathodes. Wherein the cathode is in parallel contact with the auxiliary cathodes through the metal layers, and the cathode is a transparent material or a translucent material.

In an embodiment of the present disclosure, buffer pads are disposed on surfaces of the black matrices, and the auxiliary cathodes are disposed on the buffer pads.

In an embodiment of the present disclosure, the buffer pads, the auxiliary cathodes and the metal layers are within blocking regions of the black matrices.

In an embodiment of the present disclosure, a surface of the buffer pads adjacent to the color filters and a surface of the black matrices have a pretilt angle, and the buffer pads are covered in the auxiliary cathodes.

In an embodiment of the present disclosure, the metal layers are formed on surfaces of the auxiliary cathodes and contact the black matrices.

In an embodiment of the present disclosure, a melting point of the metal layers is less than or equal to 100° C.

An embodiment of the present disclosure further provides a manufacturing method of a display panel comprising following steps:
S10: preparing an array substrate provided with an anode, a cathode, and a light-emitting layer disposed between the anode and the cathode, the array substrate provided with a pixel area, and the light-emitting layer disposed correspondingly to the pixel area;
S20: preparing a color filter substrate provided with black matrices, and color filters corresponding to the pixel area, and preparing auxiliary cathodes and metal layers on the black matrices in sequence.
S30: heating the color filter substrate until the metal layers in a molten state, attaching the array substrate to the color filter substrate correspondingly, and making the cathode contact the auxiliary cathodes in parallel through the metal layers.

In an embodiment of the present disclosure, S20 comprises following steps:
S201: preparing buffer pads on the black matrices;
S202: preparing the auxiliary cathodes on the buffer pads;
S203: preparing the metal layers on the auxiliary cathodes, wherein the buffer pads, the auxiliary cathodes and the metal layers are within a region of the black matrices.

In an embodiment of the present disclosure, in S30, the heating temperature of the color filter substrate is less than or equal to 100° C. to make the metal layers in a molten state.

To achieve the above object, an embodiment of the present disclosure further provides a display panel. The display panel comprises an array substrate, and a color filter substrate disposed opposite to the array substrate; the array substrate comprises an anode, a cathode and a light-emitting layer disposed between the anode and the cathode, the array substrate is provided with a pixel area, and the light-emitting layer is disposed correspondingly to the pixel area; the color filter substrate comprises color filters corresponding to the pixel area, and black matrices disposed between two of the adjacent color filters; the color filter substrate is provided with auxiliary cathodes corresponding to the black matrices, and metal layers are disposed on the auxiliary cathodes; wherein the cathode is in parallel contact with the auxiliary cathodes through the metal layers.

In an embodiment of the present disclosure, buffer pads are disposed on surfaces of the black matrices, and the auxiliary cathodes are disposed on the buffer pads.

In an embodiment of the present disclosure, the buffer pads, the auxiliary cathodes and the metal layers are within blocking regions of the black matrices.

In an embodiment of the present disclosure, a surface of the buffer pads adjacent to the color filters and a surface of the black matrices have a pretilt angle, and the buffer pads are covered in the auxiliary cathodes.

In an embodiment of the present disclosure, the metal layers are formed on surfaces of the auxiliary cathodes and contact the black matrices.

In an embodiment of the present disclosure, a melting point of the metal layers is less than or equal to 100° C.

The beneficial effect of the present disclosure is: compared to current display panels, a display panel and a manufacturing method thereof in an embodiment of the present disclosure can maintain a good electrical connection between auxiliary cathodes and a cathode, thereby improving non-uniform brightness of display panels by disposing metal layers with a low melting point on auxiliary cathodes; when an array substrate is bonded to a color filter substrate correspondingly, the array substrate maintains at room temperature, the color filter substrate is heated until the metal layers are in a molten state, and the melting metal layers are cooling and cured when contact the cathode at room temperature. Besides, because the auxiliary cathodes contact the cathode in parallel, it reduces the overall resistance of the cathode, ensures uniform brightness of display panels, and improving resolution of display panels.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic structural diagram of a display panel before an array substrate bonded to a color filter substrate according to an embodiment of the present disclosure.

FIG. 2 is a schematic structural diagram of a display panel after an array substrate bonded to a color filter substrate according to an embodiment of the present disclosure.

FIG. 3 is a schematic structural diagram of a display panel according to an embodiment of the present disclosure.

FIG. 4 is a manufacturing flowchart of a display panel according to an embodiment of the present disclosure.

### DETAILED DESCRIPTION OF PREFERRED EMBODIMENTS

The embodiments of the present disclosure are described in detail hereinafter, Examples of the described embodiments are given in the accompanying drawings, wherein the identical or similar reference numerals constantly denote the identical or similar elements or elements having the identical or similar functions. In the description of the present disclosure, it should be understood that terms such as “upper,” “lower,” “front,” “rear,” “left,” “right,” “inside,” “outside,” “side,” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure.

The current display panels have poor contact between an auxiliary cathode and an OLED cathode, thereby losing expected function of the auxiliary cathode and causing non-uniform brightness of display devices. Embodiments of the present disclosure can solve the problems.

As shown in FIG. 1, FIG. 1 is a schematic structural diagram of a display panel before an array substrate bonded to a color filter substrate according to an embodiment of the present disclosure. The array substrate 1 comprises: a base substrate 10, a pixel defined layer 11 is disposed on the base substrate 10, and the pixel defined layer 11 is provided with a pixel area. An anode 12, a cathode 14 and a light-emitting layer 13 disposed between the anode 12 and the cathode 14 form a plurality of light-emitting parts, and the light-emitting layer 13 is disposed correspondingly to the pixel area; the array substrate 1 further comprises array distributed thin film transistors (not marked), and one light-emitting part is corresponding to one thin film transistor. The anode 12 is array distributed, and an anode 12 is correspondingly connected to a drain of a thin film transistor.

The color filter substrate 2 comprises a glass substrate 20, color filters 21 disposed correspondingly to the pixel area array, and black matrices 22 disposed in gaps among adjacent color filters 21. A photoresist layer (not marked) is disposed on the color filters 21 and the black matrices 22, buffer pads 23 are on surfaces of black matrices 22, auxiliary cathodes 24 are disposed on the buffer pads 23. The buffer pads 23 are disposed correspondingly to the black matrices 22, or the buffer pads 23 are disposed correspondingly to the black matrices 22 in integrated network structures. Metal layers 25 are disposed on the auxiliary cathodes 24, and the metal layers 25 are metal materials with low melting points. Wherein the cathode 14 is in parallel contact with the auxiliary cathodes 24 through the metal layers 25.

The buffer pads 23, the auxiliary cathodes 24 and the metal layers 25 are within blocking regions of the black matrices 22. In an embodiment, areas of the metal layers 25 are smaller than areas of the auxiliary cathodes 24 corresponding to the metal layers 25. Materials of the auxiliary cathodes 24 comprise, but are not limited to, Al, Mo, Cu or alloys thereof.

A surface of the buffer pads 23 adjacent to the color filters 21 and a surface of the black matrices 22 have a pretilt angle, and the buffer pads 23 are covered in the auxiliary cathodes 24, Cross-sectional shapes of the buffer pads 23 comprise, but are not limited to, trapezoids, rectangles, triangles, semicircles, etc., wherein heights of the buffer pads 23 are uniform. The heights of the buffer pads 23 range from 0.2 μm to 10 μm. In other embodiments, the heights of the buffer pads 23 range from 1 μm to 5 μm, such as 2 μm, 3 μm, or 4 μm.

The cathode 14 is a transparent material or a translucent material, a transparent material is like a transparent oxide (such as indium zinc oxide), and a thickness of the cathode 14 ranges from 100 nm to 500 nm. A translucent material is like a thin metal (such as Ag, Mg:Ag). In order to maintain over 40% transmittance of a translucent cathode, a thickness of a film layer usually ranges from 10 nm to 200 nm.

The periphery of the color filter substrate 2 is provided with a sealant 26, and the sealant 26 is used to seal the array substrate 1 and the color filter substrate 2. A surface of the color filter substrate 2 is filled with transparent fillers (not marked), the transparent fillers are used for buffering when the array substrate 1 is bonded to the color filter substrate 2.

In an embodiment, the metal layers 25 are metal materials with low melting points, which comprise, but are not limited to, a bismuth-indium alloy (InₓBi_{y}), a tin-bismuth-indium alloy (InₓBi_{y}Sn_{z}), etc. A melting point can be controlled by adjusting proportions (x, y, z) of individual metals in the above alloys. In an embodiment, a melting point of the metal layers 25 is less than or equal to 100° C.

It should be understood, the array substrate 1 further comprises other conventional film layer, such as array distributed thin film transistors, and the anode 12 is connected with a drain of the thin film transistors.

As shown in FIG. 2, FIG. 2 is a schematic structural diagram of a display panel after an array substrate bonded to a color filter substrate according to an embodiment of the present disclosure.

The color filter substrate 2 is placed on a hot plate 3, the hot plate 3 is used to heat the color filter substrate 2, and the heating temperature is controlled less than or equal to 100° C. The array substrate 1 is correspondingly bonded to the color filter substrate 2 when the metal layers 25 are in a molten state. After cooling, the cathode 14 is in parallel contact with the auxiliary cathodes 24 through the metal layers 25.

This design can maintain a good electrical connection between the auxiliary cathodes 24 and the cathode 14, avoiding uneven substrate surfaces of auxiliary cathodes 24 in prior art or not controlling a spacing well between two substrates and leading poor connection of auxiliary cathodes 24 and a cathode 14 when bonding. The present disclosure provides a display panel, ensuring a good electrical connection between the auxiliary cathodes 24 and the cathode 14, thereby solving the problem of voltage drops and improving panel packaging.

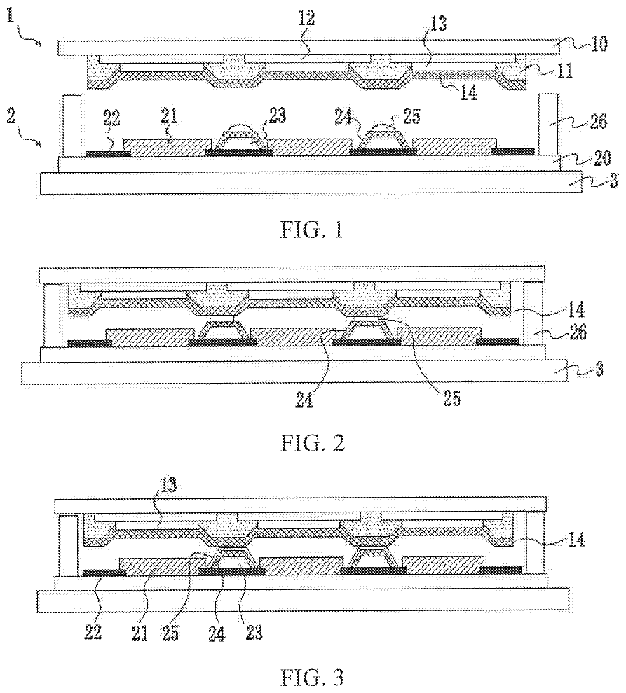

As shown in FIG. 3, FIG. 3 is a schematic structural diagram of a display panel according to an embodiment of the present disclosure. Compared with FIG. 2, in FIG. 3, the metal layers 25 are formed on surfaces of the auxiliary cathodes 24 and contact the black matrices 22; that is, the metal layers 25 comprise the auxiliary cathodes 24 and the buffer pads 23. Due to the refractive index of the metal layers 25 are higher than the auxiliary cathodes 24, it can increase transmittance of the display panel without affecting the electrical connection between the cathode 14 and the auxiliary cathodes 24 by using this design. That is, a direction of light transmitted from the light-emitting layer 13 to the black matrices 22 is reflected by the metal layers 25 and emitted through the color filters 21, thereby increasing transmittance of the display panel.

Besides, the auxiliary cathodes 24 of the present disclosure are disposed on one side of the color filter substrates 2 without occupying the area of the array substrate 1, which is beneficial to increasing resolution of the display panel. Moreover, it doesn't increase the density of metal circuits on the array substrate 1 by using the auxiliary cathodes 24, and avoids panel defects caused by a short circuit when the density of metal circuits is too high.

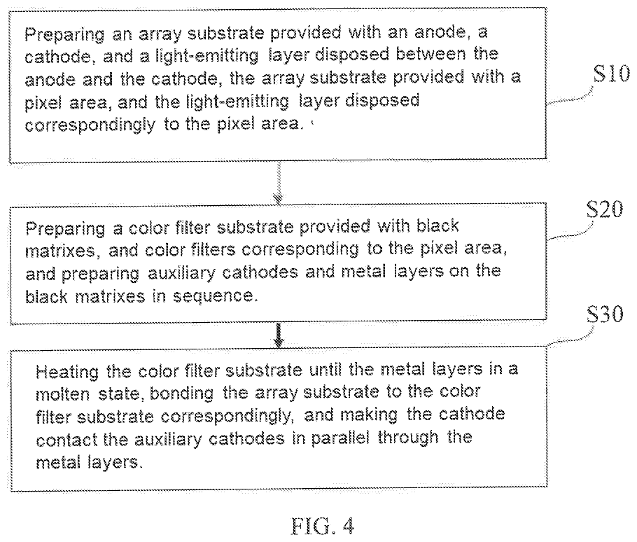

An embodiment of the present disclosure further provides a manufacturing method of a display panel. As shown in FIG. 4 and combined with FIG. 1, the method comprises following steps:

S10: preparing an array substrate provided with an anode, a cathode, and a light-emitting layer disposed between the anode and the cathode, the array substrate provided with a pixel area, and the light-emitting layer disposed correspondingly to the pixel area;

wherein preparing a thin film transistor layer, an anode 12, a pixel defined layer 11, a light-emitting layer 13 and a cathode 14 on the array substrate in sequence. The manufacturing method of the array substrate is the same as current methods which will not be iterated herein for the sake of conciseness.

S20: preparing a color filter substrate provided with black matrices, and color filters corresponding to the pixel area, and preparing auxiliary cathodes and metal layers on the black matrices in sequence;

wherein preparing the black matrices 22, the color filters 21, and a photoresist layer (over coat) on a glass substrate 20 in sequence. Wherein S20 comprises following steps:

S201: preparing buffer pads on the black matrices;

Preparing the buffer pads 23 on the photoresist layer corresponding to the black matrices 22, and the buffer pads 23 are within regions of the black matrices 22.
S202: preparing the auxiliary cathodes on the buffer pads;
S203: preparing the metal layers on the auxiliary cathodes, wherein the buffer pads, the auxiliary cathodes and the metal layers are within regions of the black matrices 22.

After that, coating a UV curing sealant to the periphery of the color filter substrate, and coating a moderate amount of transparent fillers on the color filter substrate.
S30: heating the color filter substrate until the metal layers in a molten state, bonding the array substrate to the color filter substrate correspondingly, and making the cathode contact the auxiliary cathodes in parallel through the metal layers.

Specifically, transfer the color filter substrate 2 to a bonding device, a film surface of the color filter substrate 2 is upward, and the heating plate 3 heats until the metal layers 25 with a low melting point in a molten state. Wherein the heating temperature of the color filter substrate 2 is less than or equal to 100° C., and makes the metal layers 25 achieve a molten state. Transfer the array substrate 1 to a bonding device, a film surface of the array substrate 1 is downward, pumps the cavity pressure in the bonding device and pumps it to a low pressure state. Use CCD to perform a precise alignment between the array substrate 1 and the color filter substrate 2. After bonding, restore the cavity pressure to atmospheric pressure and take out the bonded display panel to perform sealant curing and panel cutting.

As described above, the present disclosure provides a display panel and a manufacturing method thereof to maintain a good electrical connection between auxiliary cathodes and a cathode, thereby improving non-uniform brightness of display panels by disposing metal layers with a low melting point on auxiliary cathodes; when an array substrate is bonded to a color filter substrate correspondingly, the array substrate maintains at room temperature, the color filter substrate is heated until the metal layers are in a molten state, and the melting metal layers are cooling and cured when contact the cathode at room temperature. Besides, because the auxiliary cathodes contact the cathode in parallel, it reduces the overall resistance of the cathode, and ensures uniform brightness of display panels. Besides, the auxiliary cathodes are disposed on one side of the color filter substrates thereby improving resolution of display panels.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A display panel, comprising an array substrate and a color filter substrate disposed opposite to the array substrate;
the array substrate comprising an anode, a cathode and a light-emitting layer disposed between the anode and the cathode; the array substrate provided with a pixel area, and the light-emitting layer disposed correspondingly to the pixel area;
the color filter substrate comprising color filters corresponding to the pixel area, and black matrices disposed between two of the adjacent color filters;
the color filter substrate provided with auxiliary cathodes corresponding to the black matrices, and metal layers disposed on the auxiliary cathodes;
wherein the cathode is in parallel contact with the auxiliary cathodes through the metal layers, and the cathode is a transparent material or a translucent material.

2. The display panel according to claim 1, wherein buffer pads are disposed on surfaces of the black matrices, and the auxiliary cathodes are disposed on the buffer pads.

3. The display panel according to claim 2, wherein the buffer pads, the auxiliary cathodes and the metal layers are within blocking regions of the black matrices.

4. The display panel according to claim 2, wherein a surface of the buffer pads adjacent to the color filters and a surface of the black matrices have a pretilt angle, and the buffer pads are covered in the auxiliary cathodes.

5. The display panel according to claim 4, wherein the metal layers are formed on surfaces of the auxiliary cathodes and contact the black matrices.

6. The display panel according to claim 1, wherein a melting point of the metal layers is less than or equal to 100° C.

7. A manufacturing method of a display panel, comprising following steps:
S10: preparing an array substrate provided with an anode, a cathode, and a light-emitting layer disposed between the anode and the cathode, the array substrate provided with a pixel area, and the light-emitting layer disposed correspondingly to the pixel area;
S20: preparing a color filter substrate provided with black matrices, and color filters corresponding to the pixel area, and preparing auxiliary cathodes and metal layers on the black matrices in sequence.
S30: heating the color filter substrate until the metal layers in a molten state, attaching the array substrate to the color filter substrate correspondingly, and making the cathode contact the auxiliary cathodes in parallel through the metal layers.

8. The manufacturing method according to claim 7, wherein S20 comprising following steps:
S201: preparing buffer pads on the black matrices;
S202: preparing the auxiliary cathodes on the buffer pads;
S203: preparing the metal layers on the auxiliary cathodes, wherein the buffer pads, the auxiliary cathodes and the metal layers are within a region of the black matrices.

9. The manufacturing method according to claim 7, wherein in S30, the heating temperature of the color filter substrate is less than or equal to 100° C. to make the metal layers in a molten state.

10. A display panel, comprising an array substrate, and a color filter substrate disposed opposite to the array substrate;
the array substrate comprising an anode, a cathode and a light-emitting layer disposed between the anode and the cathode, the array substrate provided with a pixel area, and the light-emitting layer disposed correspondingly to the pixel area;
the color filter substrate comprising color filters corresponding to the pixel area, and black matrices disposed between two of the adjacent color filters;
the color filter substrate provided with auxiliary cathodes corresponding to the black matrices, and metal layers disposed on the auxiliary cathodes;
wherein the cathode is in parallel contact with the auxiliary cathodes through the metal layers.

11. The display panel according to claim 10, wherein buffer pads are disposed on surfaces of the black matrices, and the auxiliary cathodes are disposed on the buffer pads.

12. The display panel according to claim 11, wherein the buffer pads, the auxiliary cathodes and the metal layers are within blocking regions of the black matrices.

13. The display panel according to claim 11, wherein a surface of the buffer pads adjacent to the color filters and a surface of the black matrices have a pretilt angle, and the buffer pads are covered in the auxiliary cathodes.

14. The display panel according to claim 13, wherein the metal layers are formed on surfaces of the auxiliary cathodes and contact the black matrices.

15. The display panel according to claim 10, wherein a melting point of the metal layers is less than or equal to 100° C.
